(19) United States
(12) Patent Application Publication
(10) Pub. No.: US 2019/0379811 A1
(43) Pub. Date: Dec. 12, 2019

(54) CONNECTION STRUCTURE AND CAMERA MODULE USING SAME

(71) Applicant: HON HAI PRECISION INDUSTRY CO., LTD., New Taipei (TW)

(72) Inventors: LU-QING MENG, Shenzhen (CN); WEI-MING WU, New Taipei (TW); CHEN-KUANG YEH, New Taipei (TW); XU-GUO YANG, Shenzhen (CN)

(21) Appl. No.: 16/429,094

(22) Filed: Jun. 3, 2019

(30) Foreign Application Priority Data
Jun. 6, 2018 (TW) 107119558

(51) Int. Cl. H04N 5/225; G02B 27/64; H01L 27/146

(52) U.S. Cl. CPC H04N 5/2257; G02B 27/64; H04N 5/2253; H04N 5/2254; H04N 5/2252; H01L 27/146

(57) ABSTRACT

A camera module includes a base and at least one camera unit. The camera unit is mounted on the base, and the camera unit includes a circuit substrate, an image sensor, a lens assembly, a circuit board, a plurality of metal wires. The circuit substrate is rectangular, and has four edges and a plurality of first pads. The first pads are located along two adjacent edges of the circuit substrate. The image sensor and the lens assembly are mounted on the circuit substrate. The circuit board has two notched edges and a plurality of second pads. The second pads are located along the two notched edges of the circuit board. The second pads correspond to the first pads. Each second pad is connected to a corresponding first pad by one of the metal wires. The camera module uses wire bonding to connect the circuit substrate to the circuit board.

### FIELD

The present disclosure relates to electronic packages, and more particularly to a connection structure and a camera module using the same.

### BACKGROUND

Most mobile device manufacturers are pursuing higher screen to body ratios for better visual quality such that camera modules of the mobile devices are required to be smaller and thinner. The camera module generally includes a circuit substrate, an image sensor, a lens assembly, a circuit board, and an anisotropic conductive film (ACF). The image sensor and the lens assembly are mounted on the circuit substrate. The circuit substrate is pressed to the circuit board. The anisotropic conductive film is used for connecting the circuit substrate to the circuit board. However, the circuit substrate must have a pressed section such that the circuit substrate cannot be reduced in size and cost. In addition, pressing the circuit substrate to the circuit board causes a risk of breakage of the circuit substrate.

Therefore, there is room for improvement within the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a perspective view of an embodiment of a camera module.

FIG. 2 is an exploded perspective view of an embodiment of a camera module.

FIG. 3 is an exploded perspective view of an embodiment of a camera unit of a camera module.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

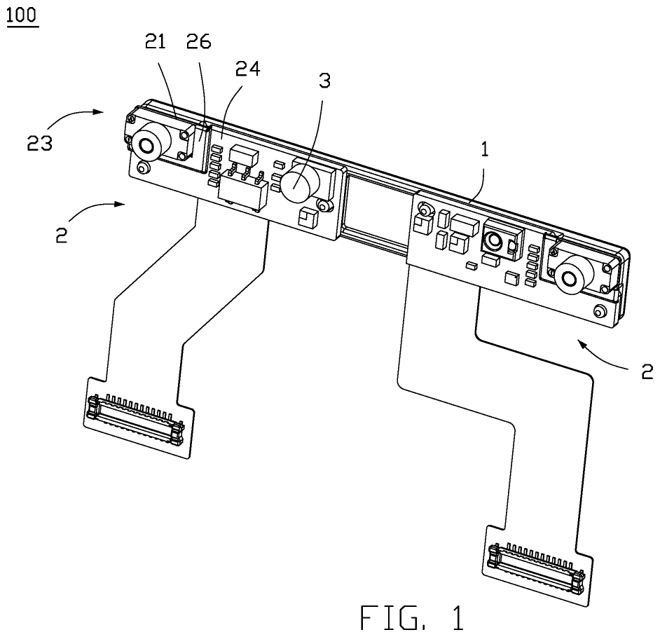

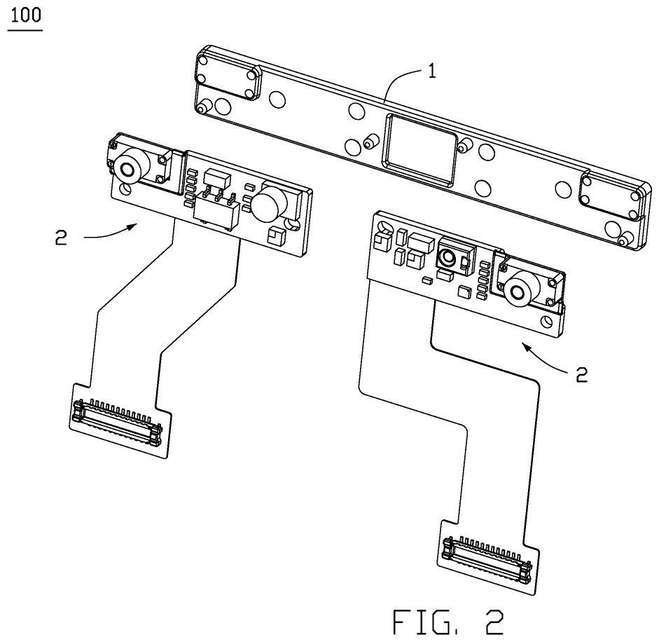

FIG. 1 is a perspective view of an embodiment of a camera module. FIG. 2 is an exploded perspective view of an embodiment of a camera module. As shown in FIGS. 1 and 2, a camera module 100 may be mounted in a housing of an electronic device (not shown). The electronic device can be, but is not limited to, a smart phone, a tablet computer, a notebook computer, a desktop computer, or a monitoring device. The camera module 100 includes a base 1 and at least one camera unit 2 mounted on the base 1.

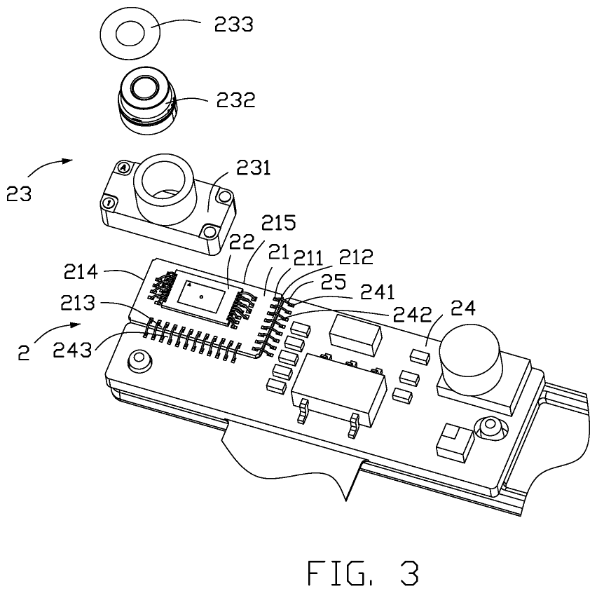

FIG. 3 is an exploded perspective view of an embodiment of a camera unit of a camera module. As shown in FIG. 3, the camera unit 2 includes a circuit substrate 21, an image sensor 22, a lens assembly 23, a circuit board 24, a plurality of metal wires 25, and an encapsulant 26. The circuit substrate 21 is rectangular, and has four edges 212, 213, 214, 215 and a plurality of first pads 211. The first pads 211 are located along two adjacent edges 212, 213 of the circuit substrate 21. The image sensor 22 and the lens assembly 23 are mounted on the circuit substrate 21. The circuit board 24 has two perpendicular notched edges 242, 243, and a plurality of second pads 241. The second pads 241 are located along the two notched edges 242, 243 of the circuit board 24. The second pads 241 correspond to the first pads 211. Each second pad 241 is connected to a corresponding first pad 211 by one of the metal wires 25. The encapsulant 26 covers the metal wires 25 to prevent rust and corrosion of the metal wires 25.

In an embodiment, the substrate 21 can be a ceramic substrate or a glass substrate. The image sensor 22 can be a charge coupled device (CCD) or a complementary metal oxide semiconductor (CMOS) sensor. The circuit board 24 can be a flexible printed circuit board or a rigid printed circuit board. The metal wires 25 can be gold wires, copper wires or silver wires. Each metal wire 25 has two ends, one end is bonded to the first pad 211 by laser welding, and the other end is bonded to the second pad 241 by laser welding. The lens assembly 23 includes a lens holder 231, a lens 232, and a lens cover 233. The lens holder 231 is mounted on the circuit substrate 21 and covers the image sensor 22. The lens 232 is inserted in the lens holder 231 and positioned in an optical path of the image sensor 22. The lens 232 can be an infrared lens. The lens cover 233 covers the lens 232 to protect the lens 232.

The camera module 100 uses wire bonding to connect the circuit substrate 21 to the circuit board 24. Therefore, the circuit substrate 21 can be reduced in size and cost because the circuit substrate 21 does not need to have a pressed section. In addition, a risk of breakage of the circuit substrate 21 can be prevented.

In an embodiment as shown in FIG. 1, the camera module 100 includes two camera units 2 and a light emitter 3. The camera module 100 can acquire a 3D image by the two camera units 2 for face recognition. The light emitter 3 is mounted on the circuit board 24 of one of the camera units 2. The light emitter 3 can be an infrared LED. The two lenses 232 are configured to receive light emitted by the light emitter 3 and reflected by an object (not shown) to assist in the acquisition of the 3D image.

The embodiments shown and described above are only examples. Many details are often found in this field of art thus many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A connection structure comprising:
a circuit substrate being rectangular, and the circuit substrate having:
four edges; and
a plurality of first pads located along two adjacent edges of the circuit substrate;
a circuit board having:
two notched edges; and
a plurality of second pads located along the two notched edges of the circuit board, and the second pads corresponding to the first pads; and
a plurality of metal wires;
wherein each second pad is connected to a corresponding first pad by one of the metal wires.

2. The connection structure of claim 1, further comprising an encapsulant covering the metal wires.

3. The connection structure of claim 1, wherein each metal wire has two ends, one end is bonded to the first pad by laser welding, and the other end is bonded to the second pad by laser welding.

4. A camera module comprising:
a base; and
at least one camera unit mounted on the base, and the camera unit comprising;
a circuit substrate being rectangular, and the circuit substrate having:
four edges; and
a plurality of first pads located along two adjacent edges of the circuit substrate;
a circuit board having:
two notched edges; and
a plurality of second pads located along the two notched edges of the circuit board, and the second pads corresponding to the first pads;
an image sensor;
a lens assembly; and
a plurality of metal wires;
wherein the image sensor and the lens assembly are mounted on the circuit substrate; and
wherein each second pad is connected to a corresponding first pad by one of the metal wires.

5. The camera module of claim 4, further comprising an encapsulant covering the metal wires.

6. The camera module of claim 4, wherein each metal wire has two ends, one end is bonded to the first pad by laser welding, and the other end is bonded to the second pad by laser welding.

7. The camera module of claim 4, wherein the lens assembly comprises:
a lens holder mounted on the circuit substrate and covering the image sensor;
a lens inserted in the lens holder and positioned in an optical path of the image sensor; and
a lens cover covering the lens.

8. The camera module of claim 4, further comprising:
two camera units; and
a light emitter mounted on the circuit board of one of the camera units.
